(19) United States
(12) Patent Application Publication
(10) Pub. No.: US 2020/0105336 A1
(43) Pub. Date: Apr. 2, 2020

(54) FAST ACCESS DRAM WITH 2 CELL-PER-BIT, COMMON WORD LINE, ARCHITECTURE

(71) Applicant: OmniVision Technologies, Inc., Santa Clara, CA (US)

(72) Inventors: Taehyung JUNG, Santa Clara, CA (US); Chia-Ming CHEN, San Jose, CA (US); Hyunsu YOON, San Jose, CA (US)

(21) Appl. No.: 16/146,726

(22) Filed: Sep. 28, 2018

(51) Int. Cl. G11C 11/408; G11C 11/4091; G11C 11/4097

(52) U.S. Cl. CPC G11C 11/4087; G11C 11/4097; G11C 11/4085; G11C 11/4091

(57) ABSTRACT

In a system, a 1T DRAM a decoder drives word lines, each driving enable transistors of true and complement DRAM cells; true DRAM cells being coupled to true bit lines, with complement DRAM cells coupled to complement bit lines. Differential sense amplifiers each receive true and complement bit lines. In a method of writing and reading DRAM, a DRAM is provided with common word lines feeding true and complement cells attached to true and complement bit lines. Writing the DRAM includes applying data to true bit lines with complement data on complement bit lines; then pulsing a selected word line to write data into true and complement cells. Reading requires pulsing precharge lines to reset true and complement bit lines; selecting a single word line to read the true and complement cells onto true and complement bit lines; and sensing differences between true and complement bit lines.

### BACKGROUND

Dynamic random access memory (RAM) (DRAM) generally occupies considerably less area per bit than does static RAM (SRAM), however one-transistor (1-T) cell DRAM typically provides weak enough read signals that 1-T DRAM is considerably slower to read than SRAM.

### SUMMARY

In an embodiment, a dynamic random access memory (DRAM) having one-transistor cells has a decoder-driver configured to drive word lines, each word line drives enable transistors of both true and complement one-transistor DRAM cells; the true DRAM cells coupled to a true bit line, with the complement one-transistor DRAM coupled to a complement bit line. Differential sense amplifiers each receive both a true bit line and a complement bit.

In another embodiment, a method of writing and reading a DRAM includes providing a DRAM with common word lines each feeding true and complement cells attached to true and complement bit lines; writing the DRAM by applying data to true bit lines, and complement data to complement bit lines; and pulsing a selected single word line of the common word lines to write data into the true and complement cells coupled to that word line. Reading then proceeds by pulsing precharge lines to reset the true and complement bit lines; raising a selected single word line of the common word lines to charge-share cell capacitors of the true and complement cells onto the true and complement bit lines; and enabling differential sense amplifiers to sense differences between true and complement bit lines.

### BRIEF DESCRIPTION OF THE FIGURES

FIG. 1 illustrates a read-channel of a 1-T DRAM system.

FIG. 2 illustrates timing of a read-channel of the 1-T DRAM system of FIG. 1.

FIG. 2A illustrates timing of the read-channel of the 1-T DRAM system of FIG. 1 when operated with two cells per bit to give a stronger signal to the sense amplifiers.

FIG. 3 illustrates a sense amplifier adaptable for use with 1-T DRAM.

FIG. 4 illustrates a dual-cell, single-word-line, DRAM.

FIG. 5 is a flow chart illustrating a method of high speed memory access.

### DETAILED DESCRIPTION OF THE EMBODIMENTS

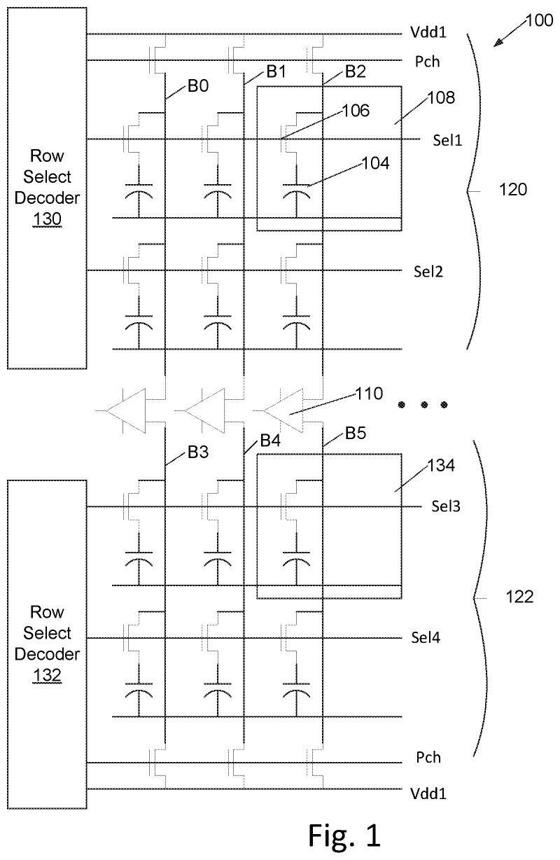

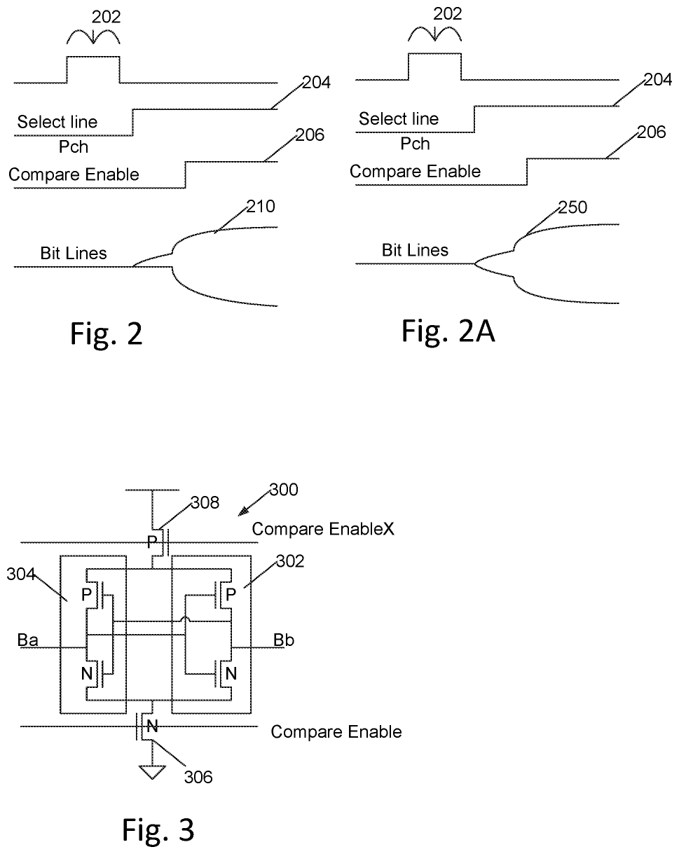

A read channel 100 of 1-T DRAM is illustrated in FIG. 1. With reference also to FIG. 2, precharge lines Pch provide a neutral value between logic 1 and logic 0 values from a reference voltage Vdd1 to precharge bit lines B0-5 during a precharge interval 202, the Pch lines are then zeroed. In a conventional 1-T DRAM, a selected single select line, for example Sel1 is raised by row decoder 130 to enable charge from capacitors 104 to pass through selection transistors 106 in selected cells 108 onto bit lines B0-B2 of a selected half 120 of the array, while remaining bit lines B3-B5 driven by a second row decoder 132 remain quiescent and no charge passes through selection transistors in unselected cells 134. The charge from capacitors 104 shares onto the bit lines B0-B2 of the selected half of the array causing a voltage change 210, these bit lines are then compared by differential sensing amplifiers 110 against bit lines B3-B5 of the unselected half of the array during a compare-enable signal 206.

An example self-refreshing differential sense amplifier 300 is illustrated in FIG. 3 In this example, two bit lines Ba, Bb couple to bit lines of the array, a first inverter 302 and second inverter 304 are cross-coupled to form a latch, with power provided through enable transistors 306, 308, the enable transistors are on during compare enable 206. Any difference between bit lines Ba, Bb causes an imbalance in amplifier 300 such that when the amplifier is powered during compare enable 206, data on bit lines Ba, Bb resolves to a solid one or zero level and may be selected by other circuitry.

In typical DRAMs, the halves 120, 122 of the array contain different data.

In a first embodiment, to provide a stronger differential signal to differential sensing amplifiers 110 and thereby decrease the time it takes to resolve signals at differential sensing amplifiers 110 and increase charge storage time on capacitors 104, true data is stored in one half of the array 120, and complement data is stored in the other half 122 of the array. In this embodiment, instead of keeping select lines of an unselected half of the array quiescent, a selected select (sel 1-2) line of array half 120 and a selected select line (Sel 3-4) of array half 122 are active for each read cycle. When read, instead of sharing onto one bit line attached to each sense amplifier, the data and data complement share onto both bit lines 250 of the sense amplifiers, driving them in opposite directions, and providing a double-strength signal at the sense amplifier, as shown in FIG. 2A.

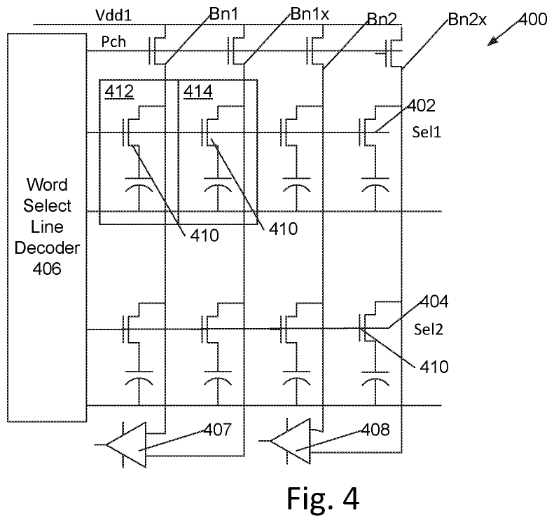

In a second embodiment of the read channel 400 of the DRAM, the array is organized in a single block, with word lines 402, 404 driven by a single word select line address decoder 406 with timing as discussed with reference to FIGS. 2 and 2A. Bit lines Bn1, Bn1x, Bn2, Bn2x are in pairs, one pair directed to each differential sense amplifier 407, 408; in a particular embodiment the differential sense amplifiers are of the type previously discussed with reference to FIG. 3. Each word line 402, 404 coupled to a selection transistor 410 of true-data cells 412 and complement-data cells 414 of each pair of bit lines, as illustrated for Bn1 and Bn1x for word line 402. In some systems, the embodiment of FIG. 4 conserves die area over embodiments with separate word lines for true and complement, like the true-and-complement variation of the DRAM of FIG. 1.

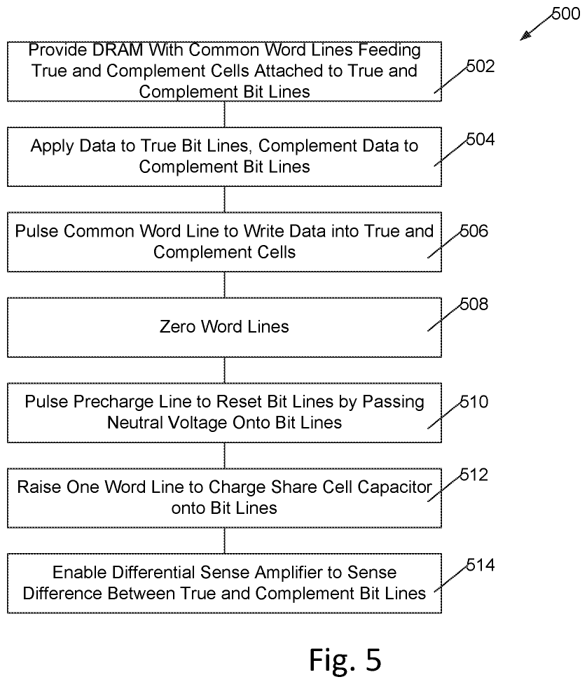

A method 500 of high speed RAM writing and reading is illustrated in the flow chart of FIG. 5. The method begins with providing 502 DRAM with common word lines feeding true and complement cells attached to true and complement bit lines. Data is then written to the DRAM by applying the data 504 to true bit lines, with complement data on complement bit lines either before or during a pulse 506 of the common word line to write data into the true and complement cells coupled to that word line, and the word lines are zeroed 508.

The DRAM is then read by pulsing 510 precharge lines to reset bit lines by passing a neutral voltage onto bit and bit-complement lines; then raising 512 one word line to charge share cell capacitors onto the bit lines and complement liens. Next, the differential sense amplifiers are enabled 514 to sense differences between true and complement bit lines, and data may then be read from the bit lines. Combinations of Features

In an embodiment designated A, a dynamic random access memory (DRAM) having one-transistor cells has a decoder-driver configured to drive word lines, each word line drives enable transistors of both true and complement one-transistor DRAM cells; the true DRAM cells coupled to a true bit line, with the complement one-transistor DRAM coupled to a complement bit line. Differential sense amplifiers each receive both a true bit line and a complement bit.

In an embodiment designated AA including the embodiment designated A, the true and complement bit lines of each pair of bit lines are configured to be written with true and complement data corresponding to a single bit of data input to the DRAM.

In another embodiment designated B, a method of writing and reading a DRAM includes providing a DRAM with common word lines each feeding true and complement cells attached to true and complement bit lines; writing the DRAM by applying data to true bit lines, and complement data to complement bit lines; and pulsing a selected single word line of the common word lines to write data into the true and complement cells coupled to that word line. Reading then proceeds by pulsing precharge lines to reset the true and complement bit lines; raising a selected single word line of the common word lines to charge-share cell capacitors of the true and complement cells onto the true and complement bit lines; and enabling differential sense amplifiers to sense differences between true and complement bit lines.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A dynamic random access memory (DRAM) having one-transistor cells, the DRAM comprising:
a decoder-driver configured to drive a plurality of common word lines, each common word line of the plurality of common word lines coupled to enable transistors of true and complement one-transistor DRAM cells;
the true one-transistor DRAM cells each coupled to a true bit line of a plurality of true bit lines;
the complement one-transistor DRAM cells each coupled to a complement bit line of a plurality of complement bit lines;
a plurality of differential sense amplifiers each coupled to receive a true bit line of the plurality of true bit lines and to receive a complement bit line of the plurality of complement bit lines, the true bit line and the complement bit line forming a pair of bit lines of the true and complement bit lines.

2. The DRAM of claim 1 wherein the true and complement bit lines of each pair of bit lines are configured to be written with true and complement data corresponding to a single bit of data input to the DRAM.

3. A method of writing and reading a DRAM comprising:
providing a DRAM with common word lines each feeding true and complement cells attached to true and complement bit lines;
writing the DRAM by applying data to true bit lines, and complement data to complement bit lines;
pulsing a selected single word line of the common word lines to write data into the true and complement cells coupled to that word line;
reading the DRAM by pulsing precharge lines to reset the true and complement bit lines;
raising a selected single word line of the common word lines to charge-share cell capacitors of the true and complement cells onto the true and complement bit lines; and
enabling differential sense amplifiers to sense differences between true and complement bit lines.
